(19) United States
(12) Patent Application Publication
(10) Pub. No.: US 2026/0113218 A1
(43) Pub. Date: Apr. 23, 2026

(54) SIGNAL PROCESSING CIRCUIT, OPTICAL TRANSMISSION DEVICE, AND OPTICAL TRANSMISSION SYSTEM

(71) Applicant: Fujitsu Limited, Kawasaki-shi (JP)

(72) Inventors: Masashi SATO, Kawasaki (JP); yoshitaka NOMURA, Shinagawa (JP); Hisao NAKASHIMA, Kawasaki (JP); KAZUHIKO HATAE, Kawasaki (JP)

(73) Assignee: Fujitsu Limited, Kawasaki-shi (JP)

(21) Appl. No.: 19/361,319

(22) Filed: Oct. 17, 2025

(30) Foreign Application Priority Data
Oct. 18, 2024 (JP) 2024-182337

(51) Int. Cl. H04L 25/03; H03H 17/06

(52) U.S. Cl. CPC H04L 25/03; H03H 17/06

(57) ABSTRACT

A signal processing circuit includes: a first finite impulse response (FIR) filter having n taps and configured to perform adaptive control processing on a received signal; a second FIR filter having N taps and used in updating a first set of tap coefficients of the first FIR filter, N being a value greater than n; and a coefficient adaptive control processing unit configured to set the first set of tap coefficients of the first FIR filter and a second set of tap coefficients of the second FIR filter, the coefficient adaptive control processing unit setting the first set of tap coefficients of the first FIR filter based on output data of the second FIR filter.

### CROSS REFERENCE TO RELATED APPLICATIONS

This application is based upon and claims the benefit of priority of the prior Japanese Patent Application No. 2024-182337, filed on Oct. 18, 2024, the entire contents of which are incorporated herein by reference.

### FIELD

The embodiments discussed herein are related to a signal processing circuit, an optical transmission device, and an optical transmission system

### BACKGROUND

Optical transmission devices, such as optical transceivers that transmit and receive optical digital coherent signals, tend to handle higher baud rates to increase capacity. Differential group delay (DGD), which the amount of separation between two signal components separated by polarization mode dispersion, is adaptively equalized and compensated by an adaptive equalizer (AEQ) provided in an optical receiver. The AEQ calculates tap coefficients that track fluctuations in transmission path characteristics using a blind equalization algorithm based on input and output data, and the AEQ performs equalization by multiplying the input data by the tap coefficients in an FIR filter. PMD stands for polarization mode dispersion. FIR filters are finite impulse response filters and have large circuit scales and power consumption that depend on the number of taps.

When the optical transmission baud rate increases, to accommodate DGD, it is necessary to increase the number of taps in the FIR filter of the AEQ to compensate for DGD, resulting in increased power consumption of the FIR filter.

Among prior arts, one example of a technique for compensating for DGD includes, for example, a CD equalizer, a least mean squares (LMS) module, and an adaptive PMD equalizer, to compensate for wavelength dispersion and polarization mode dispersion. Another example performs adaptive equalization for polarization mode dispersion by including a center-of-gravity adjustment module that measures the coupling energy of first and second subsets of filter taps and shifts the center of gravity when the coupling energy of the first subset exceeds the coupling energy of the second subset by a threshold value. A further technique calculates the position of the filtering center of gravity determined by the tap coefficients of an adaptive equalization processing unit in initial training before communication starts, and the technique approximates the tap coefficients closer to the tap center so as to minimize the difference from the tap center determined by the number of taps in the adaptive equalization processing unit. Yet another example includes a first filter that compensates polarization-independent signal distortion and a second filter that compensates polarization-dependent signal distortion with an adaptive equalization filter, and updates the tap coefficients of the first filter based on a transfer function corresponding to the polarization-independent signal distortion in the adaptive equalization filter (for example, refer to U.S. Patent Application Publication No. 2019/0036615, U.S. Pat. No. 8,705,977, Japanese Laid-Open Patent Publication No. 2012-119923, and Japanese Laid-Open Patent Publication No. 2014-233039).

### SUMMARY

According to an aspect of an embodiment, a signal processing circuit includes: a first finite impulse response (FIR) filter having n taps and configured to perform adaptive control processing on a received signal; a second FIR filter having N taps and used in updating a first set of tap coefficients of the first FIR filter, N being a value greater than n; and a coefficient adaptive control processing unit configured to set the first set of tap coefficients of the first FIR filter and a second set of tap coefficients of the second FIR filter, the coefficient adaptive control processing unit setting the first set of tap coefficients of the first FIR filter based on output data of the second FIR filter.

An object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram depicting a signal processing circuit according to a first embodiment.

FIG. 2 is a diagram depicting a signal processing circuit according to a reference example.

FIG. 3 is a diagram depicting an AEQ of the reference example.

FIG. 4 is a diagram depicting an example of a set of FIR filter tap coefficients during blind equalization.

FIG. 5A is a diagram depicting an example of tap center of gravity correction processing according to the first embodiment.

FIG. 5B is a diagram depicting an example of tap center of gravity correction processing according to the first embodiment.

FIG. 6 is a diagram explaining operation during initial startup according to the first embodiment.

FIG. 7 is an explanatory diagram of the operation during normal operation according to the first embodiment.

FIG. 8 is a flowchart depicting an example of signal processing according to the first embodiment.

FIG. 9 is a diagram depicting a signal processing circuit according to a second embodiment.

FIG. 10 is an explanatory diagram of the operation during the initial startup according to the second embodiment.

FIG. 11 is an explanatory diagram of the operation during normal operation according to the second embodiment.

FIG. 12 is a flowchart depicting an example of signal processing according to the second embodiment.

FIG. 13A is an explanatory diagram of a tap selection operation of a FIR filter.

FIG. 13B is an explanatory diagram of the tap selection operation of the FIR filter.

FIG. 14 is a diagram depicting an example of a configuration of an optical receiver.

FIG. 15 is a diagram depicting a configuration example of an optical transmission system.

### DESCRIPTION OF EMBODIMENTS

First, problems associated with the conventional techniques are discussed. For example, as the optical transmission baud rate increases, the number of taps of the FIR filter necessary to maintain DGD tolerance increases, resulting in increased power consumption.

Embodiments of a signal processing circuit, an optical transmission device, and an optical transmission system are described in detail with reference to the accompanying drawings. A signal processing circuit according to the embodiments is applied to optical digital coherent optical transmission and compensates for DGD using an AEQ disposed in an optical transmission device such as an optical receiver. In the embodiment, the DGD tolerance is improved without increasing the power consumption of the FIR filter at startup (initial startup) and during operation of an optical transmission device including an AEQ, when the transmission path characteristics of the transmission path are unknown.

In the embodiments, for example, quadrature amplitude modulation (QAM) is used for optical communication transmission.

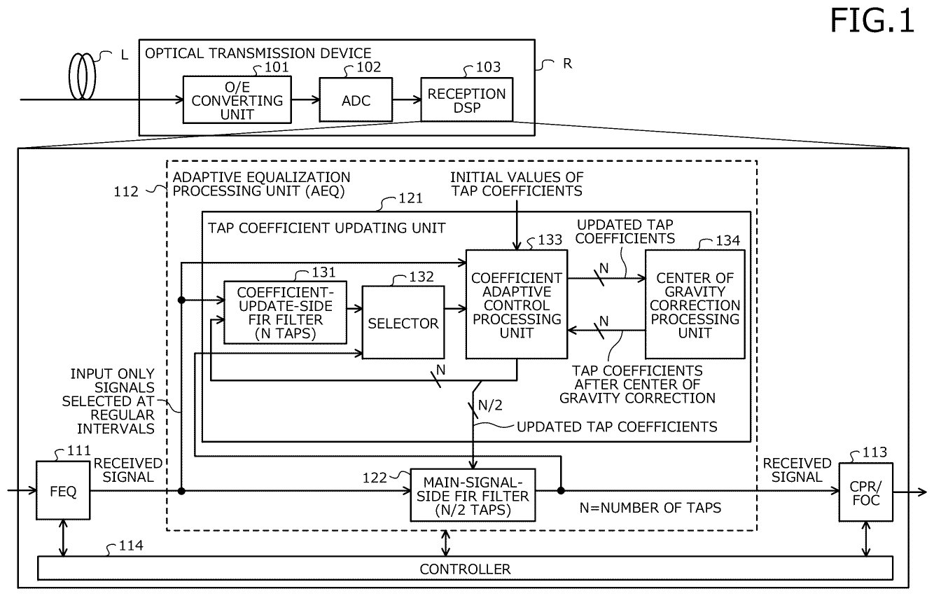

FIG. 1 is a diagram depicting a signal processing circuit according to a first embodiment. The signal processing circuit of the first embodiment corresponds to a reception digital signal processor (DSP) 103 depicted in FIG. 1. In the optical transmission system, a transmitting-side optical transmission device transmits an optical signal via an optical transmission line L, and a receiving-side optical transmission device (optical receiver) R receives the signal. The receiving-side optical transmission device R includes an O/E converting unit 101, an AD converter (ADC) 102, and the reception DSP 103. The O/E converting unit 101 opto-electrically converts the received optical signal and outputs the converted signal to the ADC 102. The ADC 102 performs analog-to-digital conversion on the electrical signal (received signal) after the opto-electric conversion and outputs the resulting signal to the reception DSP 103.

The reception DSP 103 performs data processing of the received signal and includes a fixed equalizer (FEQ) 111, an adaptive equalization processing unit (AEQ) 112, a CPR/FOC 113, and a controller 114. CPR stands for carrier phase recovery, and FOC stands for frequency offset compensation.

The FEQ 111 performs dispersion compensation, linear compensation, nonlinear compensation, etc. The adaptive equalization processing unit (AEQ) 112 performs compensation for the DGD (differential group delay) of two orthogonal polarization states, residual dispersion compensation, etc. The CPR/FOC 113 compensates for a discrepancy between the carrier frequency of the received optical signal and the frequency of the local oscillator light to restore the carrier phase. The controller 114 controls the FEQ 111, the adaptive equalization processing unit (AEQ) 112, and the CPR/FOC 113.

The adaptive equalization processing unit (AEQ) 112 includes a tap coefficient updating unit 121 and a first FIR filter (main-signal-side FIR filter 122). The main signal (received signal) output on the optical transmission line L by the FEQ 111 is input to the tap coefficient updating unit 121 and the main-signal-side FIR filter 122. The tap coefficient updating unit 121 sets a set of updated tap coefficients in the main-signal-side FIR filter 122 based on adaptive equalization control. The main-signal-side FIR filter 122 outputs the filtered received signal to the CPR/FOC 113.

The tap coefficient updating unit 121 includes a second FIR filter (coefficient-updating-side FIR filter) 131, a selector 132, a coefficient adaptive control processing unit 133, and a center of gravity correction processing unit 134.

The received signal (output of the FEQ 111) and the set of tap coefficients obtained by the coefficient adaptive control processing unit 133 are input to the coefficient-updating-side FIR filter 131. The coefficient-updating-side FIR filter 131 of the tap coefficient updating unit 121 receives a portion of the received signal.

The output of the coefficient-updating-side FIR filter 131 and the output of the main-signal-side FIR filter 122 are input to the selector 132, which selects the output of the coefficient-updating-side FIR filter 131 or the output of the main-signal-side FIR filter 122 and outputs the selected output to the coefficient adaptive control processing unit 133.

The coefficient adaptive control processing unit 133 performs tap coefficient adaptive control using a well-known blind equalization algorithm. The coefficient adaptive control processing unit 133 receives the signals input to and output from the main-signal-side FIR filter 122, calculates a set of updated tap coefficients that track fluctuations in the transmission path characteristics, and sets the set of tap coefficients in the main-signal-side FIR filter 122. The set of updated tap coefficients include tap coefficients for the orthogonal H and V polarizations.

The coefficient adaptive control processing unit 133 also obtains a set of FIR filter tap coefficients for the coefficient-updating-side FIR filter 131 or the main-signal-side FIR filter 122 selected by the selector 132, and outputs the set of FIR filter tap coefficients to the corresponding coefficient-updating-side FIR filter 131 or the main-signal-side FIR filter 122. The tap coefficient initial values are input to the coefficient adaptive control processing unit 133.

The center of gravity correction processing unit 134 receives the set of updated tap coefficients obtained by the coefficient adaptive control processing unit 133. The center of gravity correction processing unit 134 corrects the center of gravity of the updated tap coefficients for each of the orthogonal polarizations (H, V) based on the amount of deviation from the tap center. Correction of tap center deviation and bias in convergence of tap coefficients are disclosed, for example, in Japanese Laid-Open Patent Publication No. 2012-119923 mentioned above. The center of gravity correction processing unit 134 then outputs the corrected tap coefficients to the coefficient adaptive control processing unit 133.

The controller 114 selectively activates each unit of the AEQ 112 during the initial startup of adaptive equalization processing and during the normal operation after the initial startup. Functions activated/deactivated by the controller 114 during the initial startup and normal operation are described later.

In the first embodiment, the AEQ 112 includes an initial startup processing unit, and the tap coefficient updating unit 121 includes the coefficient-updating-side FIR filter 131 as a dedicated FIR filter. Unlike the main-signal-side FIR filter 122, the coefficient-updating-side FIR filter 131 extracts input data from the received signal at regular intervals. For example, a predetermined number of symbols ( 1/32 to 1/64 symbols) per frame are pulled out and extracted.

As described, during the initial startup, the coefficient-updating-side FIR filter 131 is used to determine a set of “coarse” update tap coefficients corresponding to unknown transmission path characteristics, enabling initial startup of the adaptive equalization process. When the coefficient-updating-side FIR filter 131 and the main-signal-side FIR filter 122 have the same number of taps, the power consumption during the initial startup may be reduced to 1/32 to 1/64 of that of the main-signal-side FIR filter (depending on the regular, data extraction interval).

During normal operation, the tap coefficient updating unit 121 for initial startup is stopped. Here, when the number of taps of the coefficient-updating-side FIR filter 131 is N, the number of taps of main-signal-side FIR filter 122 used during normal operation may be set to n (for example, n=N/2) which is smaller than the number N of taps of the coefficient-updating-side FIR filter 131.

Due to the set of “coarse” update tap coefficients obtained by coefficient adaptive control processing unit 133 during the initial startup, the number n of taps of main-signal-side FIR filter 122 used during the normal operation may be set to be smaller than the number N of taps of the coefficient-updating-side FIR filter 131. In addition, by the center of gravity (centroid) correction process of the tap center performed by the center of gravity correction processing unit 134 during the initial startup, the number n of taps of main-signal-side FIR filter 122 may be set to be smaller than the number N of taps of the coefficient-updating-side FIR filter 131 (for example, n=N/2; details will be described later).

In the embodiment, a method of switching the number of taps from N to n (e.g., N/2) using only the main-signal-side FIR filter 122 is not implemented because it has disadvantages in terms of circuit size and power consumption.

This is because the main-signal-side FIR filter 122 processes all received data, and an increase in the number of taps would result in a significant increase in power consumption and circuit size.

The main-signal-side FIR filter 122 and the coefficient-updating-side FIR filter 131 perform the same filter processing, but the number of FIR filters (number of filters in parallel) differs because the amount of data processed in one cycle differs. In the above example, the number of the main-signal-side FIR filters 122 in parallel is 32 to 64 times that of the coefficient-updating-side FIR filter 131.

During the initial startup, such as when the signal processing circuit (AEQ 112) is started up while the transmission characteristics of the optical transmission line L are unknown, the coefficient adaptive control processing unit 133 performs initial startup processing based on the tap coefficient initial values and the output of the coefficient-updating-side FIR filter 131. During the normal operation after initial startup, the coefficient adaptive control processing unit 133 sets a set of updated tap coefficients in the main-signal-side FIR filter 122 and performs FIR filter processing on the received signal.

Next, problems associated with a reference example will be described.

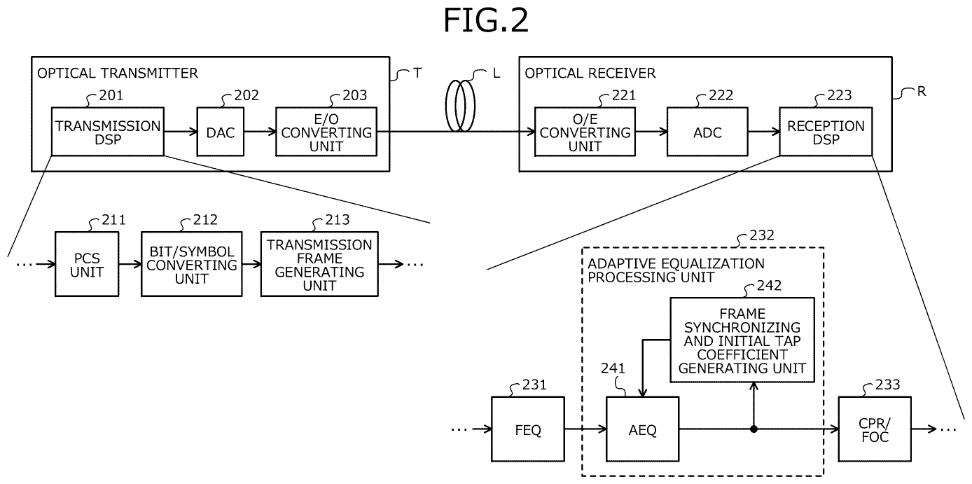

FIG. 2 is a diagram depicting a signal processing circuit according to the reference example. FIG. 2 depicts an example of the overall configuration of an optical transmission system. A transmitting-side optical transmission device (optical transmitter) T transmits an optical signal via the optical transmission line L, and a receiving-side optical transmission device (optical receiver) R receives the optical signal via the optical transmission line L.

The optical transmitter T has a transmission DSP 201, a DA converter (DAC) 202, and an E/O converting unit 203. The transmission DSP 201 has a PCS unit 211 that converts input data into PCS format, a bit/symbol converting unit 212 that maps the bits of the input PCS-converted data to symbols, and a transmission frame generation unit 213 that generates a transmission frame using the input data after the symbol conversion. The DAC 202 performs digital-to-analog conversion on the input data and outputs the result to the E/O converting unit 203. The E/O converting unit 203 converts the input data into an optical signal and sends the optical signal to the optical transmission line L.

The optical receiver R has an O/E converting unit 221, an ADC 222, and a reception DSP 223. The O/E converting unit 221 performs opto-electric conversion on the received optical signal and outputs the resulting signal to the ADC 222. The ADC 222 outputs the electrical signal (received signal) obtained by the opto-electric conversion to the reception DSP 223.

The reception DSP 223 performs data processing on the received signal and includes an FEQ 231, an adaptive equalization processing unit 232, and a CPR/FOC unit 233. The adaptive equalization processing unit 232 of the reference example includes an AEQ 241 and a frame synchronization and initial tap coefficient generating unit 242.

During the initial startup of the AEQ 241, the frame synchronization and initial tap coefficient generating unit 242 generates frame synchronization and a set of initial tap coefficients for the AEQ 241.

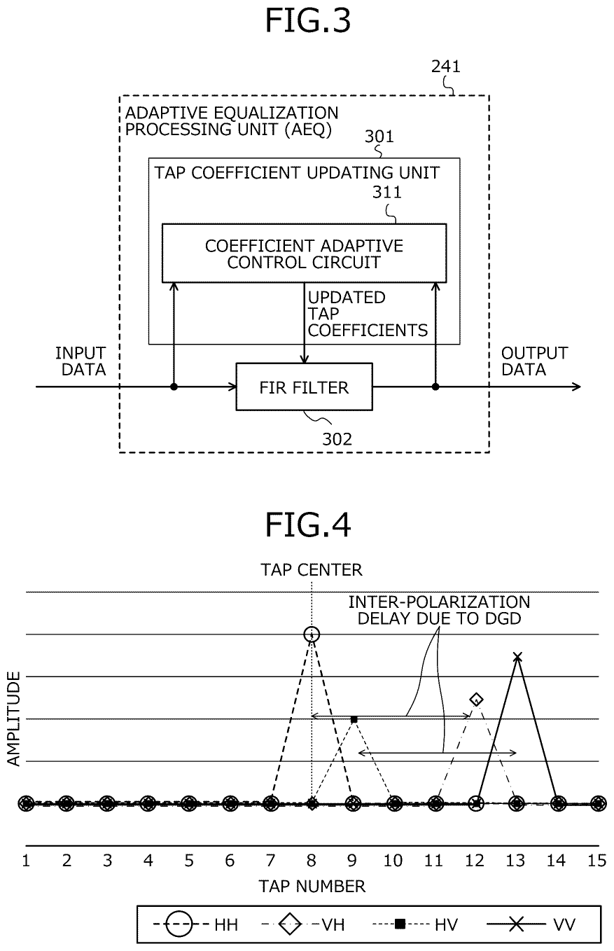

FIG. 3 is a diagram depicting the AEQ of the reference example. The AEQ 241 includes a tap coefficient updating unit 301 and an FIR filter 302. The tap coefficient updating unit 301 includes a coefficient adaptive control circuit 311. The coefficient adaptive control circuit 311 uses the input data and output data of the received signal for the FIR filter 302 to determine a set of updated tap coefficients based on a blind equalization algorithm and sets the set of updated tap coefficients in the FIR filter 302. This FIR filter 302 corresponds to the main-signal-side FIR filter 122 in the first embodiment (FIG. 1). As the baud rate of optical transmission increases, the number of taps in the FIR filter 302 of the AEQ 241 used to compensate for the DGD are increased to accommodate the same amount of DGD. For example, to accommodate a doubling of the baud rate while maintaining DGD tolerance (performance), the number of taps in the FIR filter 302 are doubled, which increases the power consumption of the FIR filter 302. In a double-baud rate environment, the amount of DGD that may be accommodated per tap interval of the FIR filter 302 is half that in a single-baud rate environment. Therefore, to accommodate the same amount of DGD, the number of taps in the FIR filter 302 have to be doubled. As a result, the circuit size of FIR filter 302 doubles compared to an environment with a baud rate of 1 and when the baud rate is doubled, the power consumption of FIR filter 302 quadruples.

In the AEQ 241 depicted in FIG. 3, the tap coefficient updating unit 301 receives input data and output data from FIR filter 302, calculates a set of tap coefficients that track fluctuations in the transmission path characteristics, and FIR filter 302 performs equalization processing by multiplying the input data by the set of tap coefficients. To accommodate a doubled baud rate while maintaining DGD tolerance, for example, the number of taps in FIR filter 302 has to be doubled, which increases power consumption.

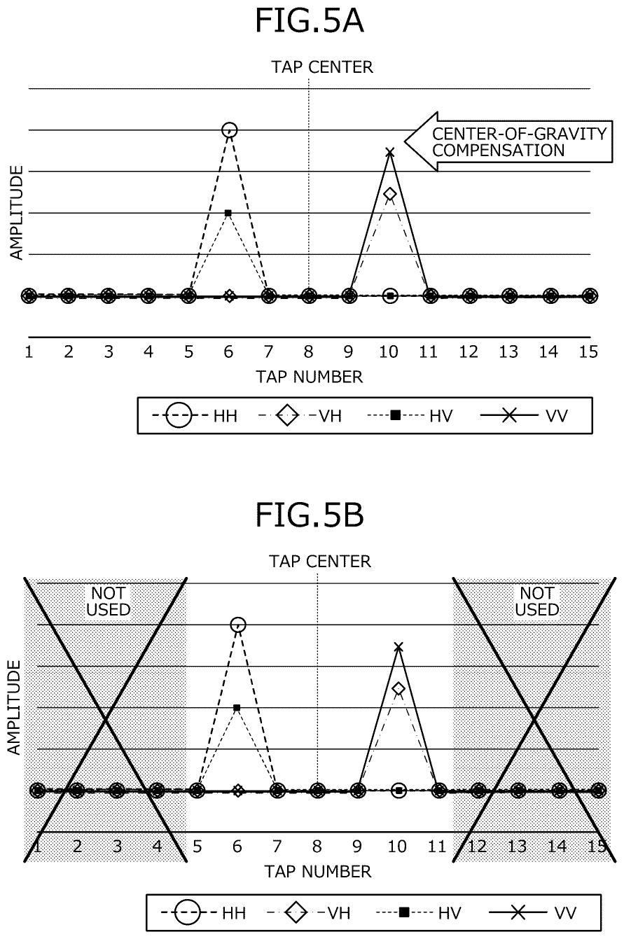

FIG. 4 is a diagram depicting an example of FIR filter tap coefficients during blind equalization. The blind equalization process performed by the coefficient adaptive control circuit 311 of the AEQ 241 may cause the tap center of gravity to shift from the tap center, and the increased inter-polarization delay due to DGD increases the possibility that the weights of the tap coefficients of the taps relative to closer to an end of the taps will be biased toward the end of the taps. When the FIR filter 302 is designed to operate even when the tap center of gravity is shifted to the maximum extent possible, the number of taps will increase.

In FIG. 4, the horizontal axis represents the tap numbers of the FIR filter 302, and the vertical axis represents the amplitude of each polarization (tap coefficients for X-axis polarization: HH, VH, tap coefficients for Y-axis polarization: HV, VV). In the example depicted in FIG. 4, the FIR filter 302 has a total of 15 taps, with the tap center being tap number 8. Due to the inter-polarization delay caused by DGD, the peaks of the tap coefficients are shifted from the tap center: HH is at tap number 8, VH is at tap number 12, HV is at tap number 9, and VV is at tap number 13. Furthermore, the weights of the tap coefficients of the taps relatively closer to an end of the taps are biased toward the end of the taps (the tap number 15).

When dealing with the inter-polarization delay due to DGD depicted in FIG. 4, with the existing techniques, the number of taps needed for the FIR filter 302 becomes large (15 taps), making low-power operation difficult. During the normal operation, when the number of taps in the FIR filter 302 is large, power consumption increases, however, reducing the number of taps needed by the FIR filter 302 is difficult, making it difficult to achieve low power consumption.

In the first embodiment, to deal with DGD while suppressing power consumption, the center of gravity correction processing unit 134 corrects the center of gravity of the updated tap coefficients for each of the orthogonal polarizations (H, V) calculated by the coefficient adaptive control processing unit 133, based on the amount of deviation from the tap center.

As depicted in FIG. 4, when the weights of the tap coefficients of the taps closer to an end of the taps are biased toward the end of the taps, an equalization residue of the AEQ 112 will occur, so it is desirable that the weights of the tap coefficients of those taps be closer to the tap center (tap number 8 in the case of 15 taps).

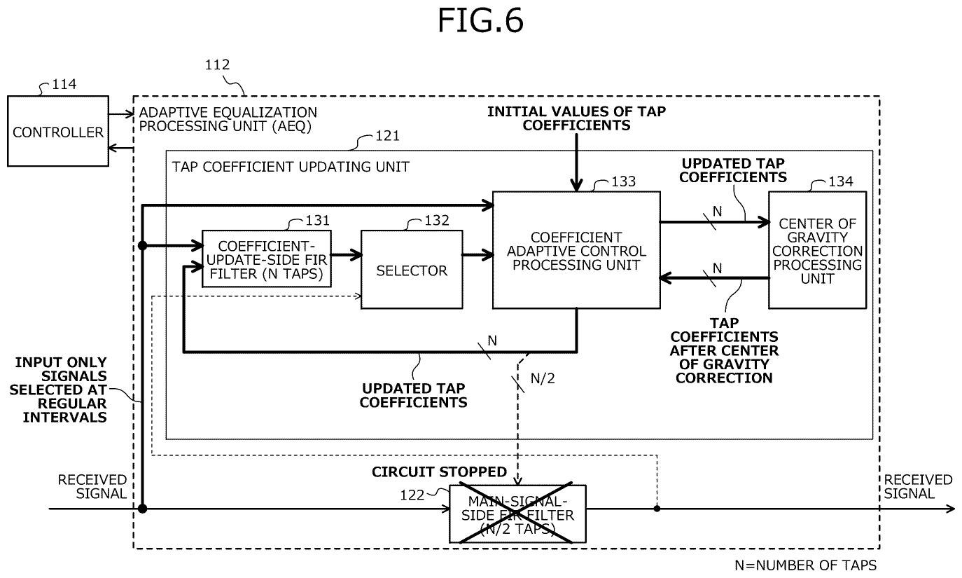

FIGS. 5A and 5B are diagrams depicting an example of tap center of gravity correction processing according to the first embodiment. The center of gravity correction processing unit 134 calculates center of gravity values of the tap coefficients. For example, as depicted in FIG. 5A, as part of the center of gravity correction processing, the center of gravity correction processing unit 134 groups HH and VH together as a set of H-side coefficients and HV and VV together as a set of V-side coefficients, and calculates the center of gravity of the set of H-side coefficients and the center of gravity of the set of V-side coefficients, respectively. The center of gravity correction processing unit 134 then shifts the corresponding taps toward the tap center by the amount of deviation from the tap center.

DGD increases the probability that the tap center of gravity of each polarization will be closer to the tap end, but by shifting all of the taps toward the tap center through center of gravity correction processing by the center of gravity correction processing unit 134, it is possible to reduce the number of taps used in the main-signal-side FIR filter 122. In the example depicted FIG. 5B, the taps used in the main-signal-side FIR filter 122 are seven taps, tap numbers 5 to 11 (about half of the total 15 taps). Tap numbers 1 to 4 and tap numbers 12 to 15, a total of eight taps, are unused. As described above, when the number of taps of the coefficient-updating-side FIR filter 131 is N, the number of taps of the main-signal-side FIR filter 122 may be set to a number of taps (e.g., N/2) smaller than the number N of taps of the coefficient-updating-side FIR filter 131.

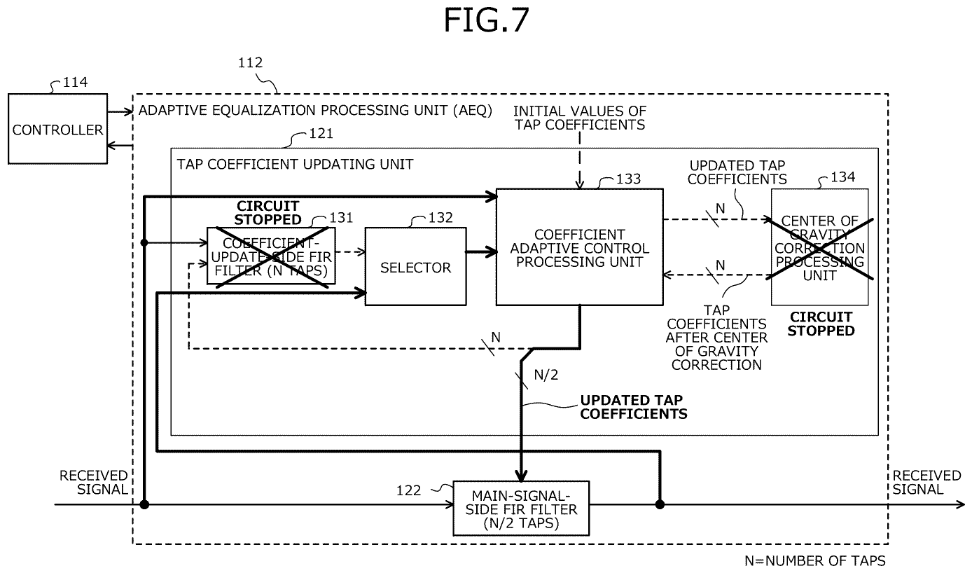

FIG. 6 is a diagram explaining operation during the initial startup according to the first embodiment. The controller 114 controls each unit of the AEQ 112, and during the initial startup of the adaptive equalization processing, as depicted in FIG. 6, operates the tap coefficient updating unit 121 of the AEQ 112 and stops the main-signal-side FIR filter 122.

The controller 114 then sets a set of tap coefficient initial values in the coefficient adaptive control processing unit 133 of the tap coefficient updating unit 121 and causes the coefficient adaptive control processing unit 133 to calculate a set of updated tap coefficients through adaptive equalization control using the set of tap coefficient initial values. At this time, the controller 114 switches the selector 132 arranged on the input side of the coefficient adaptive control processing unit 133 to select output data from the coefficient-updating-side FIR filter 131 and output the selected data to the coefficient adaptive control processing unit 133. The coefficient adaptive control processing unit 133 receives input of the received signal (input data of the main-signal-side FIR filter 122) and data output from the coefficient-updating-side FIR filter 131. The signal path during the initial startup is indicated by bold lines.

Here, during the initial startup, only signals selected from the received signal at a constant cycle (for example, a predetermined number of symbols ( 1/32 to 1/64 symbols) per frame) are input to the coefficient-updating-side FIR filter 131. The coefficient adaptive control processing unit 133 determines a set of update tap coefficients during the initial startup based on the set of tap coefficient initial values, the received signal, and the output of the coefficient-updating-side FIR filter 131 selected by the selector 132. A center of the determined set of update tap coefficients is corrected by the center of gravity correction processing unit 134, based on the amount of deviation of the set of update tap coefficients from the tap center, and the resulting set of update tap coefficients is returned to the coefficient adaptive control processing unit 133. The set of update tap coefficients after the center deviation correction is fed back and input to the coefficient-updating-side FIR filter 131. This allows the number of taps corresponding to the set of update tap coefficients determined during the initial startup to be reduced by N/2.

Furthermore, the coefficient-updating-side FIR filter 131 used during initial startup has a tap count N (e.g., N=15), but operates only on input of signals selected from the received signal at a constant interval, thereby reducing power consumption during the initial startup.

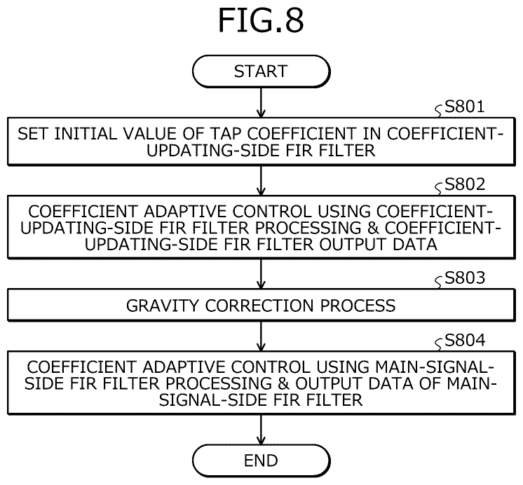

FIG. 7 is an explanatory diagram of the operation during the normal operation according to the first embodiment. The controller 114 controls the various components of the AEQ 112, and during the normal operation of adaptive equalization processing, as depicted in FIG. 7, stops the coefficient-updating-side FIR filter 131 of the tap coefficient updating unit 121 of the AEQ 112 and the center of gravity correction processing unit 134, and controls the operation of the main-signal-side FIR filter 122.

As a result, during the normal operation, the signal path (depicted by the bold lines in the figure) is the same as that of existing techniques. During the normal operation, the controller 114 switches the selector 132 on the input side of the coefficient adaptive control processing unit 133 to select the output data of the main-signal-side FIR filter. As a result, the coefficient adaptive control processing unit 133 determines a set of update tap coefficients for the main-signal-side FIR filter 122 to be used during the normal operation, based on the input data and output data for the main-signal-side FIR filter 122. The main-signal-side FIR filter 122 needs only N/2 taps, thereby reducing power consumption.

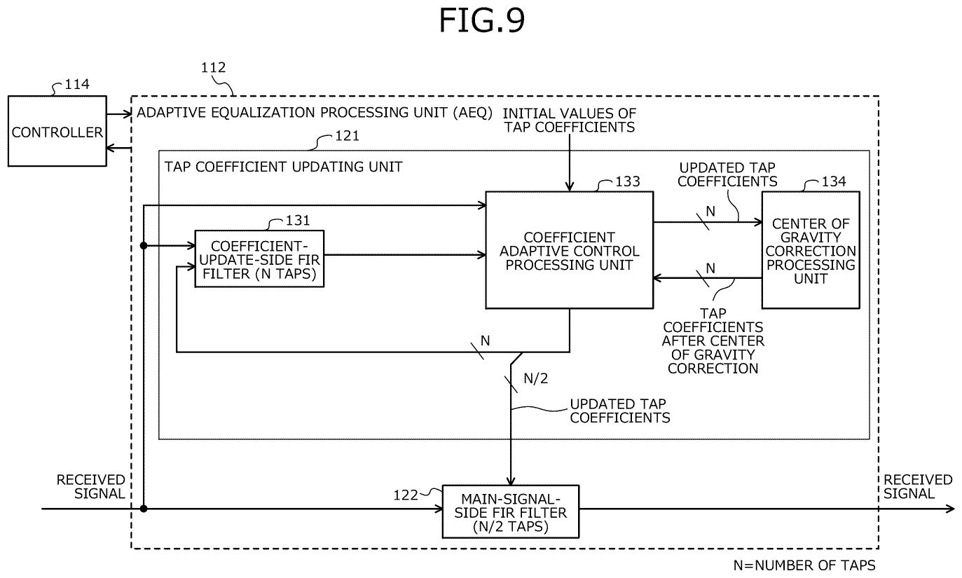

FIG. 8 is a flowchart depicting an example of signal processing according to the first embodiment. An example of signal processing by each unit of the AEQ 112 under the control of the controller 114 will be described.

During the initial startup, the controller 114 sets tap coefficient initial values in the coefficient-updating-side FIR filter 131 (step S801).

Then, the controller 114 causes the coefficient-updating-side FIR filter 131 to perform processing, and the coefficient adaptive control processing unit 133 to perform coefficient adaptive control to determine a set of update tap coefficients using output data from the coefficient-updating-side FIR filter 131 (step S802). At this time, the controller 114 stops the operation of the main-signal-side FIR filter 122 and causes the center of gravity correction processing unit 134 to correct the tap center shift of the set of updated tap coefficients (step S803).

Thereafter, during the normal operation, the controller 114 causes the coefficient adaptive control processing unit 133 to perform processing by the main-signal-side FIR filter 122 and coefficient adaptive control using the output data of the main-signal-side FIR filter 122 (step S804). During the normal operation, the controller 114 suspends the operation of the coefficient-updating-side FIR filter 131 and the center of gravity correction processing unit 134.

According to the first embodiment, the set of tap coefficients is updated using the tap coefficient updating unit 121 only during initial startup. At this time, the center of gravity correction processing unit 134 corrects a center of gravity of the set of updated tap coefficients based on the amount of deviation from the tap center. The main-signal-side FIR filter 122 has n taps (e.g., N/2), while the coefficient-updating-side FIR filter 131 has N taps. However, input data is extracted from the received signal at regular intervals and filtered using the FIR filter. This improves DGD tolerance during initial startup without increasing power consumption. Furthermore, the number of taps of the main-signal-side FIR filter 122 used during the normal operation may be n taps (e.g., n=N/2), which is smaller than the normal number of taps N. The increase in power consumption during the initial startup of the coefficient-updating-side FIR filter 131 is short and small compared to the main-signal-side FIR filter 122, and does not impact increases in power consumption overall. Furthermore, according to the first embodiment, even when the baud rate is doubled, power consumption doubles as compared to being quadrupled in the conventional case. An effect of the embodiment in reducing power consumption of is doubled compared to the existing techniques, achieving lower power consumption.

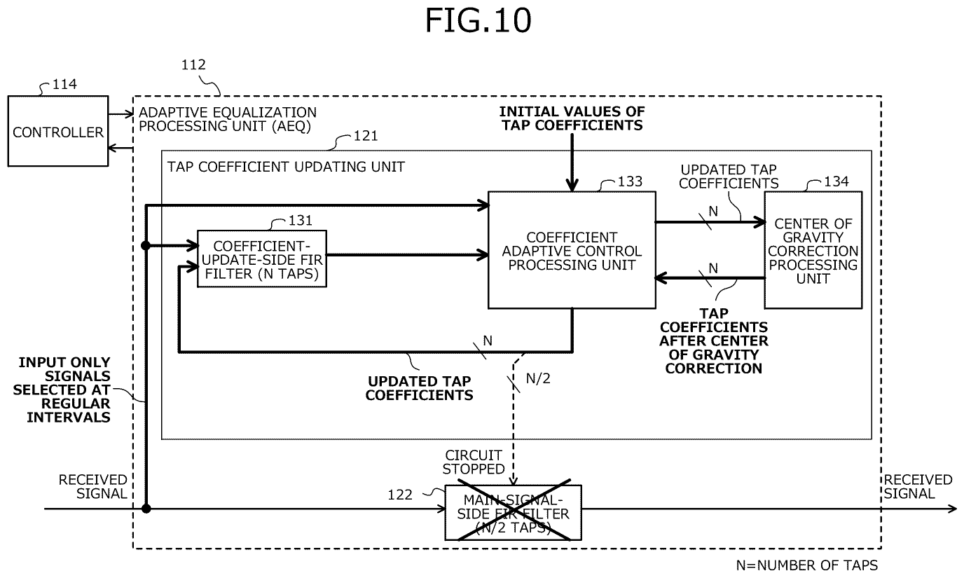

FIG. 9 is a diagram depicting a signal processing circuit according to a second embodiment. In the AEQ 112 depicted in FIG. 9, the same components as those depicted in the first embodiment (FIGS. 6 and 7) are designated by the same reference numerals used in the first embodiment. The second embodiment differs mainly in that the selector 132 described in the first embodiment is omitted. The set of update tap coefficients output by the coefficient adaptive control processing unit 133 is input to the main-signal-side FIR filter 122 and the coefficient-updating-side FIR filter 131. Furthermore, while the coefficient-updating-side FIR filter 131 operates continuously during the initial startup and normal operation, the coefficient-updating-side FIR filter 131 operates with different numbers of taps during the initial startup and normal operation.

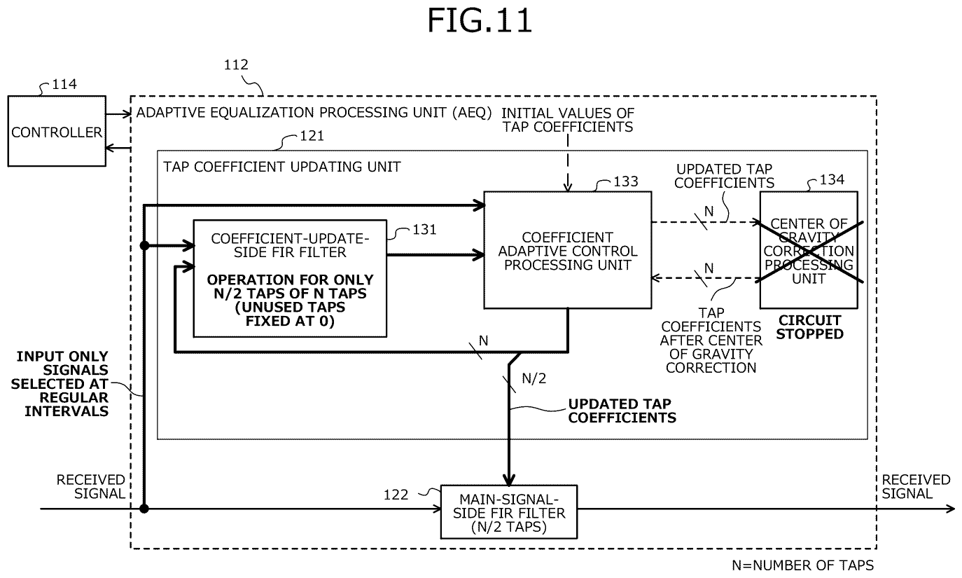

FIG. 10 is an explanatory diagram of the operation during the initial startup according to the second embodiment. The controller 114 controls each unit of the AEQ 112, and during the initial startup of the adaptive equalization process, as depicted in FIG. 10, operates the tap coefficient updating unit 121 of the AEQ 112 and stops the main-signal-side FIR filter 122. The controller 114 controls each unit of the AEQ 112, and during the initial startup of the adaptive equalization process, as depicted in FIG. 6, operates the tap coefficient updating unit 121 of the AEQ 112 and stops the main-signal-side FIR filter 122.

Then, the controller 114 sets tap coefficient initial values in the coefficient adaptive control processing unit 133 of the tap coefficient updating unit 121 and causes the coefficient adaptive control processing unit 133 to calculate a set of updated tap coefficients through adaptive equalization control using the tap coefficient initial values. At this time, the output data of the coefficient-updating-side FIR filter 131 is output to the coefficient adaptive control processing unit 133. The received signal (input data of the main-signal-side FIR filter 122) and the output data of the coefficient-updating-side FIR filter 131 are input to the coefficient adaptive control processing unit 133. The signal path during initial startup is indicated by thick lines.

Here, during initial startup, only signals selected from the received signal at a constant period (for example, a predetermined number of symbols per frame ( 1/32 to 1/64 symbols)) are input to the coefficient-updating-side FIR filter 131. The coefficient adaptive control processing unit 133 obtains a set of updated tap coefficients during initial startup based on the tap coefficient initial values, the received signal, and the output of the coefficient-updating-side FIR filter 131. The obtained set of updated tap coefficients is returned to the coefficient adaptive control processing unit 133 after the center of gravity correction processing unit 134 corrects the center of gravity based on the deviation of the set of updated tap coefficients from the tap center. The set of updated tap coefficients for which center-deviation is corrected is fed back to the coefficient-updating-side FIR filter 131. This allows the number of taps corresponding to the set of updated tap coefficients obtained during initial startup to be reduced by, for example, N/2.

The coefficient-updating-side FIR filter 131 used during initial startup has a number of taps N (e.g., N=15), but operates only on inputs of signals selected from the received signal at regular intervals, thereby reducing power consumption during initial startup.

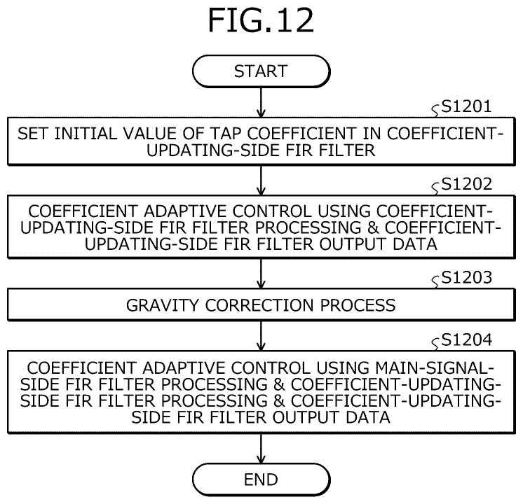

FIG. 11 is an explanatory diagram of operation during the normal operation according to the second embodiment. The controller 114 controls the various components of the AEQ 112, and during normal adaptive equalization, as depicted in FIG. 11, stops the center of gravity correction processing unit 134 of the AEQ 112 and controls the operation of the main-signal-side FIR filter 122. Furthermore, only signals selected from the received signal at regular intervals (for example, a predetermined number of symbols ( 1/32 to 1/64 symbols) per frame) are input to the coefficient-updating-side FIR filter 131 of tap coefficient updating unit 121 of AEQ 112. Then, controller 114 operates the coefficient-updating-side FIR filter 131 for only a portion of N taps, number n (n=N/2), of the N taps. As will be described later, taps may be selectively operated by controlling the tap coefficients of unused tap numbers to be fixed at 0.

As a result, during the normal operation, a signal path similar to that of existing techniques (bold lines in the figure) is obtained. During the normal operation, the coefficient adaptive control processing unit 133 obtains a set of update tap coefficients for the main-signal-side FIR filter 122 to be used during the normal operation, based on input data to main-signal-side FIR filter 122 and output data from coefficient-updating-side FIR filter 131. The number of taps of main-signal-side FIR filter 122 may be reduced, for example to N/2 taps, thereby reducing power consumption.

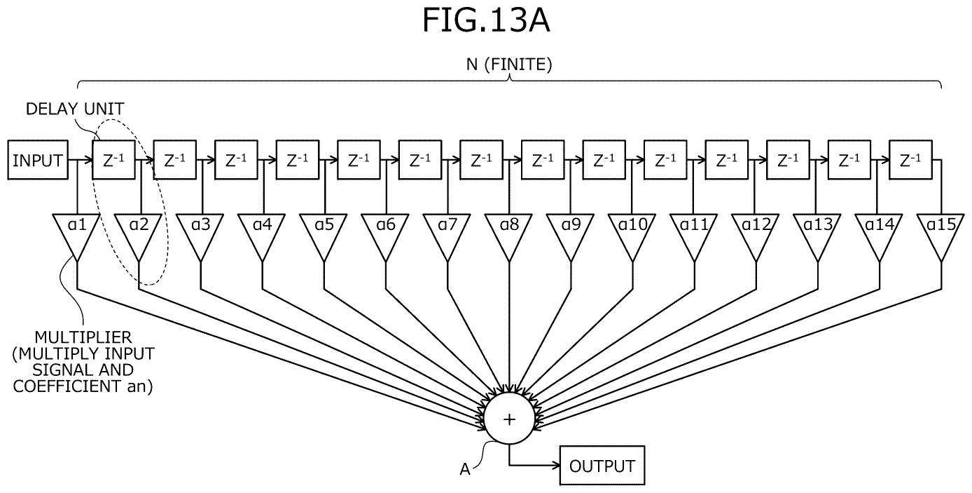

FIG. 12 is a flowchart depicting an example of signal processing according to the second embodiment. An example of signal processing by each unit of the AEQ 112 under the control of the controller 114 will be described. During the initial startup, the controller 114 sets tap coefficient initial values to the coefficient-updating-side FIR filter 131 (step S1201).

The controller 114 then causes the coefficient-updating-side FIR filter 131 to perform processing, and the coefficient adaptive control processing unit 133 to perform coefficient adaptive control for obtaining a set of update tap coefficients using output data from the coefficient-updating-side FIR filter 131 (step S1202). At this time, the controller 114 stops the operation of the main-signal-side FIR filter 122 and causes the center of gravity correction processing unit 134 to correct the tap center deviation of the set of updated tap coefficients (step S1203).

Thereafter, during the normal operation, the controller 114 causes the coefficient adaptive control processing unit 133 to perform processing by the main-signal-side FIR filter 122, processing by the coefficient-updating-side FIR filter 131, and coefficient adaptive control using the output data of the coefficient-updating-side FIR filter 131 (step S1204). During the normal operation, the controller 114 operates the coefficient-updating-side FIR filter 131 for only N/2 taps out of the N taps, and stops the operation of the center of gravity correction processing unit 134. The main-signal-side FIR filter 122 operates with N/2 taps.

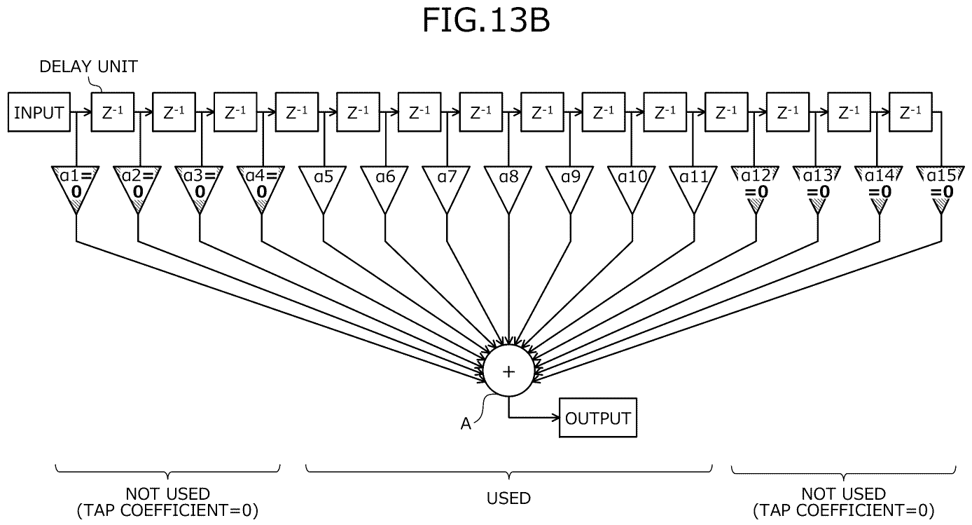

FIGS. 13A and 13B are explanatory diagrams of the tap selection operation of the FIR filter. FIG. 13A depicts an example of the internal configuration of the coefficient-updating-side FIR filter 131 and the main-signal-side FIR filter 122.

In FIG. 13A, N is the number of taps, and α1 to αn (N=n, N, n are 15 in the above example) are the tap coefficients of the multipliers for each tap. The tap coefficients α0 to αn are coefficients by which the input intensity is multiplied by the delay amount of each cascade-connected delay unit Z (Z⁻¹). The number of taps N indicates the number of stages of the delay unit Z, and the tap coefficients α0 to αn corresponding to the number N of taps are added and output from an adder A.

In the first embodiment, during the initial startup, the coefficient-updating-side FIR filter 131 performs FIR filter processing using the total number of taps N, as depicted in FIG. 13A. Furthermore, during the normal operation in the second embodiment, when N/2 taps are used, the taps near the center (tap coefficients α5 to α11) are used with consideration of the offset of the tap center of gravity, and the tap coefficients of the taps near either end (tap coefficients α1 to α4, α12 to α15) are set to 0. The controller 114 controls the tap coefficients α1 to α15 to 0. The N/2 taps of the main-signal-side FIR filter 122 correspond to the 7 taps used in FIG. 13B.

The above description describes an example in which the total number of taps N of the FIR filter is changed to n (e.g., n=N/2). Reducing the number of taps by N/2 is just one example, and design considerations regarding the extent to which the tap number (number of taps) is reduced are discussed. For example, in FIG. 5B, the spread of tap coefficients for one polarization (the distribution in which the tap coefficients have valid values) is about 7 taps. This spread of tap coefficients is determined by the amount of DGD. Considering the offset of the tap center of gravity, initial startup is possible with a number of taps of about DGD±(DGD/2)=DGD×2.

By correcting the center of gravity using the center of gravity correction processing unit 134 and shifting the tap center toward the center, only the number of taps for the DGD are needed, so n may be reduced to 1/2 the number of taps N.

In the second embodiment, the coefficient-updating-side FIR filter 131 operates continuously during the initial startup and normal operation. This results in a slight increase in power consumption compared to the first embodiment, but the selector 132 used in the first embodiment is omitted, resulting in a correspondingly smaller processing delay, enabling faster tap coefficient updating than in the first embodiment.

During the initial startup, while the number of taps of the coefficient-updating-side FIR filter 131 is N, the input data is extracted from the received signal at regular intervals and filtered through the FIR filter. This makes it possible to improve DGD tolerance without increasing power consumption during the initial startup. During the normal operation, the number of taps in the coefficient-updating-side FIR filter 131 and the main signal-side FIR filter 122 is N/2, may can suppress increases in the overall power consumption.

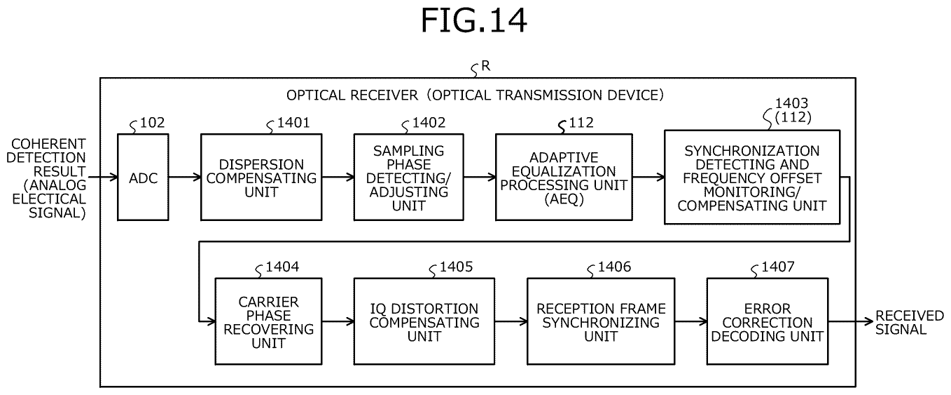

FIG. 14 is a diagram depicting an example of the configuration of an optical receiver. The signal processing circuit described above may be applied to the optical receiver R disposed on the receiving side of the optical transmission device depicted in FIG. 14. In FIG. 14, the same functions as those depicted in FIG. 1 are assigned the same reference numerals used in FIG. 1. The signal processing circuit depicted in FIG. 1 corresponds to a function of the adaptive equalization processing unit (AEQ) 112 depicted in FIG. 14.

As depicted in FIG. 14, in the optical receiver R, the ADC 102 receives the coherent detection result of the received signal (analog electrical signal), converts the signal to a digital signal, and outputs the digital signal. A dispersion compensating unit 1401 compensates for waveform distortion caused by dispersion such as polarization mode dispersion (PMD). A sampling phase detecting/adjusting unit 1402 adjusts the phase position when sampling digital data and outputs the result to the adaptive equalization processing unit 112. The adaptive equalization processing unit 112 performs coefficient adaptive control processing using the above-mentioned blind equalization algorithm.

A synchronization detecting and frequency offset monitoring/compensating unit 1403 detects and compensates for the difference (frequency offset) between the carrier frequency of the received signal and the frequency of the local oscillator light. A carrier phase recovering unit 1404 includes the above-mentioned CPR function and recovers the phase of the carrier wave. For example, the amount of frequency offset may be detected using a well-known method, and the frequency offset is compensated for by reverse-rotating the constellation at a phase rotation speed corresponding to the detected frequency error.

An IQ distortion compensating unit 1405 compensates for IQ distortion (IQ imbalance, IQ imperfection, etc.) occurring within the optical receiver R. A reception frame synchronizing unit 1406 performs frame synchronization of the receive signal. An error correction decoding unit 1407 corrects bit errors using an error correction code generated by an FEC (forward error correction code) decoder, decodes the received signal, and outputs it.

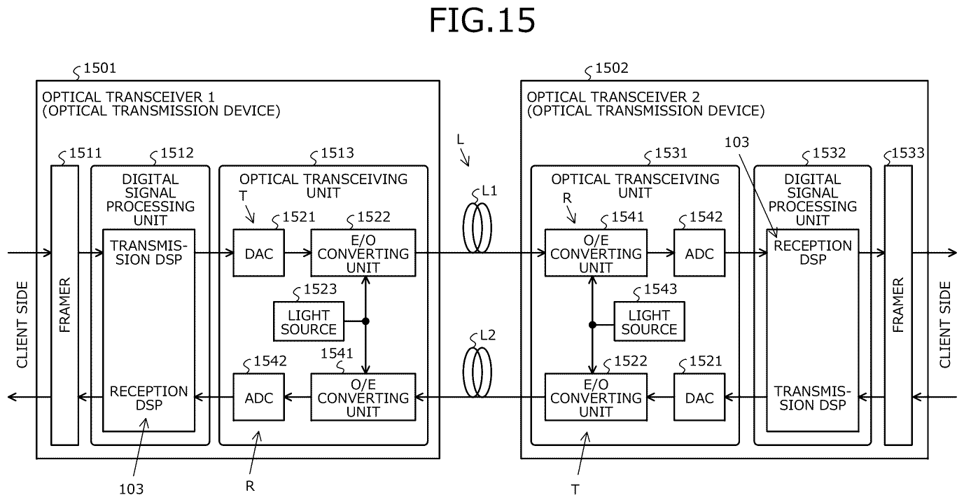

FIG. 15 is a diagram depicting a configuration example of an optical transmission system. The signal processing circuits described in the above-mentioned first and second embodiments have been described using an optical receiver disposed on the receiving side of an optical transmission device as an example. As depicted in FIG. 15, optical transceivers 1 and 2 (1501 and 1502) are disposed as optical transmission devices at both ends of an optical transmission path L, respectively.

In the optical transceiver 1 (1501), the transmitting side T sends an optical signal via downstream optical transmission path L1, and the receiving side R of the optical transceiver 2 (1502) receives the optical signal. On the other hand, the transmitting side T of the optical transceiver 2 (1502) sends out an optical signal via the upstream optical transmission line L2, and the receiving side R of the optical transceiver 1 (1501) receives the optical signal.

The components of the transmitting side T of the optical transceiver 1 (1501) are as follows: the framer 1511 frames the input signal from the client on the optical transceiver 1 (1501) side, and the transmission DSP of a digital signal processing unit 1512, which is configured a DSP, performs data processing on the transmission signal. In an optical transceiving unit 1513, the DAC 1521 performs digital-to-analog conversion of the transmission signal, the E/O converting unit 1522 converts the electrical signal to an optical signal and sends the optical signal to the optical transmission line L1. A light source 1523 is a local light source that generates the optical signal to be transmitted, and the optical signal is transmitted after undergoing predetermined optical modulation.

The components of the receiving side R of the optical transceiver 2 (1502) are as follows: the O/E converting unit 1541 of an optical transceiving unit 1531 converts the optical signal to an electrical signal, and the ADC 1542 performs analog-to-digital conversion of the received signal. The light source 1543 is a local light source that demodulates the received optical signal. The reception DSP of a digital signal processing unit 1532, which is configured by a DSP, performs reception processing. This reception DSP corresponds to the reception DSP 103 depicted in FIG. 1 described above and includes functions of the adaptive equalization processing unit 112. The output of the reception DSP is framed via a framer 1533 and output as an output signal to the client on the optical transceiver 2 (1502) side.

The components of the reception side R of the optical transceiver 1 (1501) are the same as the components of the reception side R of the optical transceiver 2 (1502). Furthermore, the components of the transmission side T of the optical transceiver 2 (1502) are the same as the components of the transmission side T of the optical transceiver 1 (1501). In FIG. 15, identical components are denoted by the same reference numerals.

As depicted in FIG. 15, each optical transmission device (optical transceiver) disposed at each end of the optical transmission path L has functions of an optical transmitter T and an optical receiver R. The optical receiver R may be implemented by the adaptive equalization processing unit (AEQ) 112 described in the above embodiment.

Currently, the adaptive equalization processing unit 112 uses a dedicated DSP because high-speed signal processing is necessary. However, the adaptive equalization processing unit 112 may also be configured using an ASIC or FPGA that supports high-speed processing. Furthermore, a high-speed CPU may be used as the controller 114 of the adaptive equalization processing unit 112 in the future. ASIC is the abbreviation for application specific integrated circuit, and FPGA is the abbreviation for field programmable gate array.

The signal processing circuit of the embodiment described above includes the first FIR filter with n taps that performs adaptive control processing of a received signal, the second FIR filter with N taps (N is a value greater than n) that is used to update the set of tap coefficients (first set of tap coefficients) of the first FIR filter, and the coefficient adaptive control processing unit that sets the set of tap coefficients of the first FIR filter and the tap coefficients (second set of tap coefficients) of the second FIR filter. The coefficient adaptive control processing unit sets the tap coefficients of the first FIR filter based on data output from the second FIR filter. For example, the first FIR filter is used during initial startup of the equalization control process when the transmission path characteristics are unknown, and the second FIR filter is used during the normal operation after the initial startup. This improves DGD tolerance without increasing the power consumption of the FIR filter.

The signal processing circuit of the embodiment also includes the center of gravity correction processing unit that corrects the deviation of the tap coefficients determined by the coefficient adaptive control processing unit from the tap center of the second FIR filter. The center of gravity correction process corrects the deviation of the second FIR filter from the tap center due to the inter-polarization delay of the DGD and makes it possible to shift the tap numbers of the updated tap coefficients closer to the center of all taps, thereby making it possible to set the number of taps of the FIR filter to n, which is smaller than the total number of taps N. Correcting the deviation of the second FIR filter from the tap center due to the inter-polarization delay of the DGD reduces the number of taps of the second FIR filter, thereby making it possible to reduce power consumption.

In the signal processing circuit of the first embodiment, during the initial startup, the coefficient adaptive control processing unit performs coefficient adaptive control of the second FIR filter based on input data to the second FIR filter and output data of the second FIR filter, and during steady-state operation after completion of the initial startup process, the coefficient adaptive control processing unit performs coefficient adaptive control based on the input data and output data of the first FIR filter. In the signal processing circuit of the second embodiment, during initial startup, the coefficient adaptive control processing unit performs coefficient adaptive control of the second FIR filter based on input data to the second FIR filter and output data from the second FIR filter. During steady-state operation after the initial startup process is complete, the coefficient adaptive control processing unit performs coefficient adaptive control based on the input data and output data from the second FIR filter. As a result, the first digital filter operates with a small number of taps n, thereby suppressing an increase in power consumption during steady-state operation and improving DGD tolerance without increasing the power consumption of the FIR filter.

The signal processing circuit of the first embodiment includes the selector that selectively switches between the output of the second FIR filter and the output of the first FIR filter. The selector selects the output of the second FIR filter during the initial startup and selects the output of the first FIR filter during steady-state operation. As described, the initial startup and subsequent steady-state operation may be easily performed by switching the selector signal.

In the signal processing circuit of the first embodiment, during the initial startup processing, the second FIR filter and the center of gravity correction processing unit operate, while the first FIR filter is stopped. During steady-state operation, the first FIR filter and only n taps out of the N taps of the second FIR filter operate, while the center of gravity correction processing unit is stopped. In the signal processing circuit of the second embodiment, during the initial startup processing, the second FIR filter and the center of gravity correction processing unit operate, while the first FIR filter is stopped. During steady-state operation, only the first FIR filter and only n taps out of the N taps of the second FIR filter operate, while the center of gravity correction processing unit is stopped. This allows processing during the initial startup to be performed and enables a smooth transition to subsequent processing during steady-state operation.

The signal processing circuit of the second embodiment sets the tap coefficients of tap numbers that are not used in the second FIR filter to 0.

Power consumption may be reduced by the number of unused taps in the second FIR filter.

In the signal processing circuit of the embodiment, the number n of taps is set to N/2 of the number N of taps, and the coefficient adaptive control processing unit uses the set of tap coefficients of the second FIR filter for n taps including the tap number of the center tap of the N taps to determine the tap coefficients of the first FIR filter. This reduces power consumption by the reduced number of taps n.

In the signal processing circuit of the embodiment, the second FIR filter extracts and uses input data from the received signal at regular intervals. This reduces the power consumption of the second FIR filter.

The optical transmission device of the embodiment receives and processes a signal received via an optical transmission line. The optical transmission device includes the O/E converter that converts the received optical signal into an electrical signal, the ADC that performs analog-to-digital conversion of the received signal converted by the O/E converter, and the above-mentioned signal processing circuit that receives and processes the received signal output by the ADC. As described, the signal processing circuit may be applied to optical transmission devices such as an optical receiver that receives an optical reception signal.

Also, an optical transmission system according to the embodiment includes the first optical transmission device that transmits an optical transmission signal to an optical transmission path, and the second optical transmission device that receives and processes the optical reception signal received via the optical transmission path. The first optical transmission device transmits a transmission signal. The second optical transmission device includes the above-mentioned signal processing circuit. As described, the signal processing circuit may be applied to an optical transmission system that transmits and receives optical signals between the first optical transmission device and the second optical transmission device.

According to one aspect of the present invention, DGD tolerance may advantageously be improved without increasing the power consumption of the FIR filter.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A signal processing circuit comprising:
a first finite impulse response (FIR) filter having n taps and configured to perform adaptive control processing on a received signal;
a second FIR filter having N taps and used in updating a first set of tap coefficients of the first FIR filter, N being a value greater than n; and
a coefficient adaptive control processing unit configured to set the first set of tap coefficients of the first FIR filter and a second set of tap coefficients of the second FIR filter, the coefficient adaptive control processing unit setting the first set of tap coefficients of the first FIR filter based on output data of the second FIR filter.

2. The signal processing circuit according to claim 1, further comprising:
a center of gravity correction processing unit configured to correct a deviation of the second set of tap coefficients determined by the coefficient adaptive control processing unit, the deviation thereof being from a tap center of the second FIR filter.

3. The signal processing circuit according to claim 2, wherein
during initial startup, the coefficient adaptive control processing unit executes coefficient adaptive control of the second FIR filter based on input data for the second FIR filter and output data of the second FIR filter, and
during steady-state operation after completion of the initial startup processing, the coefficient adaptive control processing unit executes coefficient adaptive control based on input data and output data of the first FIR filter.

4. The signal processing circuit according to claim 2, wherein
during initial startup, the coefficient adaptive control processing unit executes coefficient adaptive control of the second FIR filter based on input data for the second FIR filter and output data of the second FIR filter, and
during steady-state operation after completion of the initial startup processing, the coefficient adaptive control processing unit executes coefficient adaptive control based on input data and output data of the second FIR filter.

5. The signal processing circuit according to claim 3, further comprising
a selector configured to selectively switch output between output of the second FIR filter and output of the first FIR filter, the selector selecting the output of the second FIR filter during the initial startup processing, and selecting the output of the first FIR filter during the steady-state operation.

6. The signal processing circuit according to claim 3, wherein
during the initial startup processing, the second FIR filter and the center of gravity correction processing unit operate and the first FIR filter is stopped, and
during the steady-state operation, the first FIR filter operates and the second FIR filter and the center of gravity correction processing unit are stopped.

7. The signal processing circuit according to claim 4, wherein
during the initial startup processing, the second FIR filter and the center of gravity correction processing unit operate and the first FIR filter is stopped, and
during the steady-state operation, the first FIR filter and only n taps of the N taps of the second FIR filter operate and the center of gravity correction processing unit is stopped.

8. The signal processing circuit according to claim 7, wherein
the second set of tap coefficients includes a tap coefficient for a tap number designated as unused, and
the second FIR filter sets the tap coefficient for the tap number designated as unused to 0.

9. The signal processing circuit according to claim 1, wherein
the n taps are N/2 of the N taps, and
the coefficient adaptive control processing unit uses n of the second set of tap coefficients of the second FIR filter for the n taps that includes a tap having a tap number of a center of the N taps, the coefficient adaptive control processing unit using the n of the second set of tap coefficients in setting the first set of tap coefficients of the first FIR filter.

10. The signal processing circuit according to claim 1, wherein
the second FIR filter extracts input data from the received signal at regular intervals and uses the extracted data.

11. An optical transmission device configured to receive and process an optical signal received via an optical transmission path, the optical transmission device comprising:
an O/E converting unit that converts the received optical signal into an electrical signal;
an ADC that performs analog-to-digital conversion of the electrical signal output by the O/E converting unit, the ADC converting the electrical signal into a digital signal and outputting digital signal; and
a signal processing circuit configured to receive and process the digital signal output by the ADC, the signal processing circuit having:
a first finite impulse response (FIR) filter that has n taps and performs adaptive control processing of the digital signal;
a second FIR filter that has N taps and is used in updating a first set of tap coefficients of the first FIR filter, N being a value greater than n; and
a coefficient adaptive control processing unit configured to set the first set of tap coefficients of the first FIR filter and a second set of tap coefficients of the second FIR filter, the coefficient adaptive control processing unit setting the first set of tap coefficients of the first FIR filter based on output data of the second FIR filter.

12. An optical transmission system comprising:
a first optical transmission device that transmits a signal to an optical transmission path; and
a second optical transmission device that receives and processes the signal received via the optical transmission path, wherein
the second optical transmission device has a signal processing circuit that includes:
a first finite impulse response (FIR) filter that has n taps and performs adaptive control processing of the received signal;
a second FIR filter that has N taps and is used in updating a first set of tap coefficients of the first FIR filter, N being a value greater than n; and
a coefficient adaptive control processing unit that sets the first set of tap coefficients of the first FIR filter and a second set of tap coefficients of the second FIR filter, the coefficient adaptive control processing unit setting the first set of tap coefficients of the first FIR filter based on output data of the second FIR filter.
